(19) United States
(12) Patent Application Publication
(10) Pub. No.: US 2021/0056425 A1
(43) Pub. Date: Feb. 25, 2021

(54) METHOD AND SYSTEM FOR HYBRID MODEL INCLUDING MACHINE LEARNING MODEL AND RULE-BASED MODEL

(71) Applicant: SAMSUNG ELECTRONICS CO., LTD., Suwon-si (KR)

(72) Inventors: Changwook JEONG, Hwaseong-si (KR); Sanghoon Myung, Goyang-si (KR); In Huh, Seoul (KR); Hyeonkyun Noh, Gwangmyeong-si (KR); Minchul Park, Hwaseong-si (KR); Hyunjae Jang, Hwaseong-si (KR)

(73) Assignee: SAMSUNG ELECTRONICS CO., LTD., Suwon-si (KR)

(21) Appl. No.: 16/910,908

(22) Filed: Jun. 24, 2020

(30) Foreign Application Priority Data
Aug. 23, 2019 (KR) 10-2019-0103991
Dec. 11, 2019 (KR) 10-2019-0164802

(51) Int. Cl. G06N 3/08; G06N 20/00; G06K 9/62

(52) U.S. Cl. CPC G06N 3/084; G06K 9/623; G06K 9/6262; G06N 20/00

(57) ABSTRACT

A method for a hybrid model that includes a machine learning model and a rule-based model, includes obtaining a first output from the rule-based model by providing a first input to the rule-based model, and obtaining a second output from the machine learning model by providing the first input, a second input, and the obtained first output to the machine learning model. The method further includes training the machine learning model, based on errors of the obtained second output.

### CROSS-REFERENCE TO RELATED APPLICATIONS

This application claims priority to Korean Patent Application No. 10-2019-0103991, filed on Aug. 23, 2019, and Korean Patent Application No. 10-2019-0164802, filed on Dec. 11, 2019, in the Korean Intellectual Property Office, the disclosures of which are incorporated by reference herein in their entireties.

### BACKGROUND

The disclosure relates to modeling, and more particularly, to a method and a system for a hybrid model including a machine learning model and a rule-based model.

A modeling technique may be used to estimate an object or phenomenon having a causal relationship, and a model generated through the modeling technique may be used to predict or optimize the object or phenomenon. For example, the machine learning model may be generated by training (or learning) based on a large amount of sample data, and the rule-based model may be generated by at least one rule defined based on physical laws and the like. The machine learning model and the rule-based model may have different characteristics and thus may be applicable to different fields and have different advantages and disadvantages. Accordingly, a hybrid model that minimizes the disadvantages of the machine learning model and the rule-based model and maximizes the advantages thereof may be very useful.

### SUMMARY

According to an aspect of an example embodiment, there is provided a method for a hybrid model that includes a machine learning model and a rule-based model, the method including obtaining a first output from the rule-based model by providing a first input to the rule-based model, and obtaining a second output from the machine learning model by providing the first input, a second input, and the obtained first output to the machine learning model. The method further includes training the machine learning model, based on errors of the obtained second output.

According to another aspect of an example embodiment, there is provided a method for a hybrid model that includes a machine learning model and a rule-based model, the method including obtaining an output from the machine learning model by providing an input to the machine learning model, and evaluating the obtained output by providing the obtained output to the rule-based model. The method further includes training the machine learning model, based on a result of the obtained output being evaluated.

According to another aspect of an example embodiment, there is provided a method for a hybrid model that includes a plurality of machine learning models and a plurality of rule-based models, the method including obtaining a first output from a first rule-based model by providing a first input to the first rule-based model, and obtaining a second output from a first machine learning model by providing a second input to the first machine learning model. The method further includes obtaining a third output by providing the obtained first output and the obtained second output to a second rule-based model or a second machine learning model, and training the first machine learning model, based on errors of the obtained third output.

According to another aspect of an example embodiment, there is provided a system for a hybrid model that includes a machine learning model and a rule-based model, the system including at least one computer subsystem, and at least one component that is executed by the at least one computer subsystem. The at least one component includes the rule-based model configured to obtain a first output from a first input, based on at least one predefined rule, the machine learning model configured to obtain a second output from the first input, a second input, and the obtained first output, and a model trainer configured to train the machine learning model, based on errors of the obtained second output.

According to another aspect of an example embodiment, there is provided a system for a hybrid model that includes a machine learning model and a rule-based model, the system including at least one computer subsystem, and at least one component that is executed by the at least one computer subsystem. The at least one component includes the machine learning model configured to obtain an output from an input, the rule-based model configured to evaluate the obtained output, based on at least one predefined rule, and a model trainer configured to train the machine learning model, based on a result of the obtained output being evaluated.

According to another aspect of an example embodiment, there is provided a system for a hybrid model that includes a plurality of machine learning models and a plurality of rule-based models, the system including at least one computer subsystem, and at least one component that is executed by the at least one computer subsystem. The at least one component includes a first rule-based model configured to obtain a first output from a first input, based on at least one predefined rule, a first machine learning model configured to obtain a second output from a second input, a second rule-based model or a second machine learning model configured to obtain a third output from the obtained first output and the obtained second output, and a model trainer configured to train the first machine learning model, based on errors of the obtained third output.

### BRIEF DESCRIPTION OF THE DRAWINGS

Example embodiments of the disclosure will be more clearly understood from the following detailed description taken in conjunction with the accompanying drawings in which:

FIG. 1 is a block diagram of a hybrid model according to an example embodiment;

FIG. 2 is a block diagram of an example of a hybrid model according to an embodiment;

FIG. 3 is a flowchart of a method for the hybrid model of FIG. 2 according to an example embodiment;

FIG. 4 is a flowchart of a method for a hybrid model according to an example embodiment;

FIG. 5 is a graph showing a performance of a hybrid model according to an example embodiment;

FIG. 6 is a block diagram of an example of a hybrid model according to an example embodiment;

FIG. 7 is a graph showing a performance of the hybrid model of FIG. 6, according to an example embodiment;

FIG. 8 is a flowchart of a method for a hybrid model according to an example embodiment;

FIG. 9 is a flowchart of a method for a hybrid model according to an example embodiment;

FIG. 10 is a block diagram of an example of a hybrid model according to an example embodiment;

FIG. 11 is a block diagram of an example of a hybrid model according to an example embodiment;

FIG. 12 is a flowchart of a method for the hybrid model of FIG. 11, according to an example embodiment;

FIG. 13 is a graph showing a performance of a hybrid model according to an example embodiment;

FIGS. 14A and 14B are block diagrams of examples of hybrid models according to example embodiments;

FIG. 15 is a flow diagram of a method for the hybrid models of FIGS. 14A and 14B, according to an example embodiment;

FIG. 16 is a block diagram of a physical simulator including a hybrid model according to an example embodiment;

FIG. 17 is a block diagram of a computing system including a memory storing a program according to;

FIG. 18 is a block diagram of a computer system accessing a storage medium storing a program according to;

FIG. 19 is a flowchart of a method for a hybrid model according to; and

FIG. 20 is a flowchart of a method for a hybrid model according to.

### DETAILED DESCRIPTION

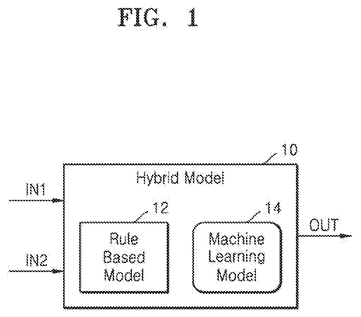

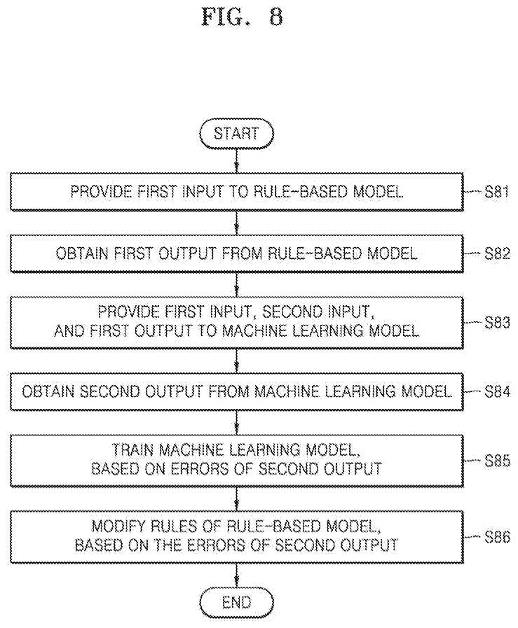

FIG. 1 is a block diagram of a hybrid model 10 according to an example embodiment. As illustrated in FIG. 1, the hybrid model 10 may generate an output OUT from a first input IN1 and a second input IN2, and include a rule-based model 12 and a machine learning model 14. In embodiments, a model trainer for training the machine learning model 14 may be included in the hybrid model 10 or located outside the hybrid model 10. In embodiments, the model trainer may modify (or correct) a rule included in the rule-based model 12 as described with reference to FIGS. 8 to 10 below.

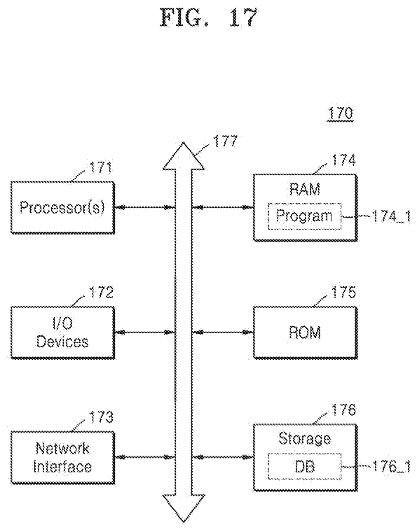

The hybrid model 10 may be implemented by any computing system (e.g., a computing system 170 of FIG. 17) to model an object or a phenomenon. For example, the hybrid model 10 may be implemented in a stand-alone computing system or distributed computing systems that are capable of communicating with each other through a network or the like. The hybrid model 10 may include a part implemented by a processor executing a program including a series of instructions and a part implemented by logic hardware designed by logic synthesis. In the present specification, a processor may refer to a hardware-implemented data processing device, including a circuit physically structured to execute predefined operations including operations expressed in instructions and/or code in a program. Examples of the data processing device may include a microprocessor, a central processing unit (CPU), a graphics processing unit (GPU), a neural processing unit (NPU), a processor core, a multi-core processor, a multi-processor, an application-specific integrated circuit (ASIC), an application-specific instruction-set processor (ASIP), and a field programmable gate array (FPGA).

A rule-based model based on at least one predefined rule and a machine learning model based on a large amount of sample data may each have unique advantages and disadvantages due to different features. For example, the rule-based model may be easy for humans to understand and require a relatively small amount of data. Thus, the rule-based model may provide relatively high explainability and generalizability but may be applicable to relatively limited areas and provide relatively low predictability. On the other hand, the machine learning model may not be easy for humans to understand and may require a large amount of sample data. Accordingly, the machine learning model may provide relatively low generalizability and low explainability but may be applicable to wide areas range and provide relatively high predictability. As will be described below with reference to the drawings, in the hybrid model 10 according to embodiments, the rule-based model 12 and the machine learning model 14 are integrated together to maximize the advantages of the rule-based model 12 and the machine learning model 14 and minimize the disadvantages thereof, thereby providing high modeling accuracy and reducing costs.

The first input IN1 and the second input IN2 may correspond to at least some of factors affecting an object or a phenomenon to be modeled by the hybrid model 10, and the output OUT may represent a state or a change of the object or the phenomenon. The first input IN1 may correspond to factors that affect the output OUT and for which rules are defined, and the second input IN2 may correspond to factors that affect the output OUT and for which rules are not defined. In the present specification, the first input IN1 may be referred to as an input for the rule-based model 12, and the second input IN2 may be referred to as an input not for the rule-based model 12. In embodiments, the second input IN2 may be omitted.

The rule-based model 12 may include at least one rule defined by the first input IN1. For example, the rule-based model 12 may include at least one formula defined by the first input IN1 and include at least one condition that the first input IN1 may satisfy. In embodiments, the rule-based model 12 may include any one or any combination of a physical simulator, an emulator modeled on the physical simulator, an analytical rule, a Heuristic rule, and an experience rule, to which at least a portion of the first input IN1 is input. For example, the rule-based model 12 may include at least one model, e.g., a spice model used for circuit simulation, which uses electrical values, e.g., voltage, current, and the like as inputs. Rules included in the rule-based model 12 may be defined based on physical phenomena, and the rule-based model 12 may be referred to as a physical model herein.

The machine learning model 14 may have any structure that may be trained by machine learning. Examples of the machine learning model 14 may include an artificial neural network, a decision tree, a support vector machine, a Bayesian network, and/or a genetic algorithm. Objects or phenomena may not be completely modeled by the rules included in the rule-based model 12, and the machine learning model 14 may supplement parts not modeled by the rules. Non-limiting examples of the hybrid model 10 including the rule-based model 12 and the machine learning model 14 and non-limiting examples of a method for the hybrid model 10 will be described with reference to drawings below.

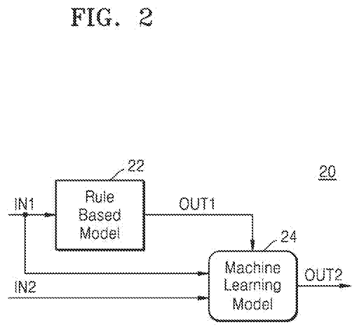

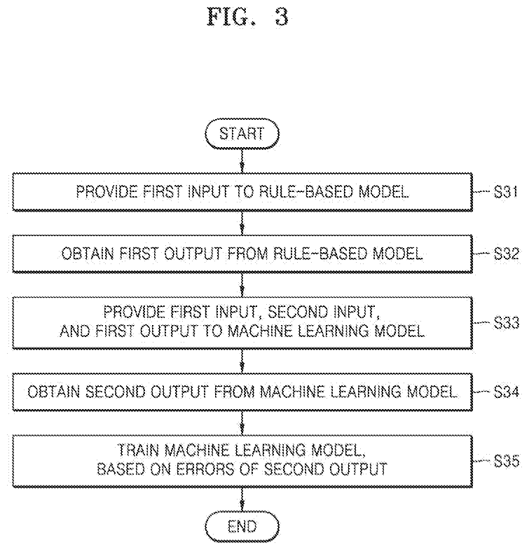

FIG. 2 is a block diagram of an example of a hybrid model 20 according to an example embodiment. FIG. 3 is a flowchart of a method for the hybrid model 20 of FIG. 2, according to an example embodiment. As illustrated in FIG. 2, the hybrid model 20 may include a rule-based model 22 and a machine learning model 24, and may receive a first input IN1 and a second input IN2 and output a second output OUT2 as the output OUT of FIG. 1 as described above with reference to FIG. 1. As illustrated in FIG. 3, a method for the hybrid model 20 may include a plurality of operations S31 to S35. In embodiments, the method of FIG. 3 may be performed by a model trainer.

Referring to FIG. 3, a first input IN1 may be provided to the rule-based model 22 in operation S31, and a first output OUT1 may be obtained from the rule-based model 22 in operation S32. As described above with reference to FIG. 1, the first input IN1 may be defined as an input for the rule-based model 22. As illustrated in FIG. 2, the rule-based model 22 may generate the first output OUT1 from the first input IN1, based on at least one predefined rule. In embodiments, the rule-based model 22 may include a plurality of parameters to be used to generate the first output OUT1 from the first input IN1, and each of the plurality of parameters may be a constant and thus may not be changeable.

In operation S33, the first input IN1, a second input IN2, and the first output OUT1 may be provided to the machine learning model 24. In operation S34, a second output OUT2 may be obtained from the machine learning model 24. As described above with reference to FIG. 1, the second input IN2 may correspond to factors that are not for the rule-based model 22 but affect an output, i.e., the second output OUT2 of FIG. 2. As illustrated in FIG. 2, the machine learning model 24 may receive the first input IN1, as well as the second input IN2, and the rule-based model 22 may receive the first output OUT1 generated from the first input IN1. As the machine learning model 24 further receives the first input IN1 and the first output OUT1, the rules included in the rule-based model 22 may be reflected in the machine learning model 24, thereby improving the accuracy of the second output OUT2. The machine learning model 24 may have been learned (or trained) by samples of the first input IN1, the second input IN2, the first output OUT1, and the second output OUT2, and the second output OUT2 may be generated from the first input IN1, the second input IN2, and the first output OUT1, based on the learned state thereof.

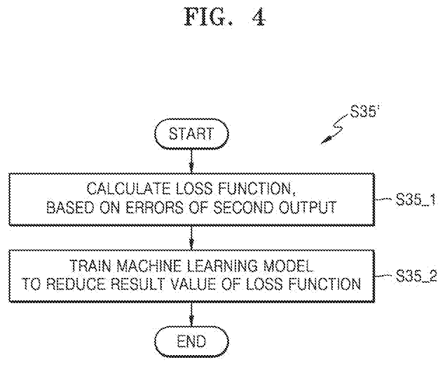

In operation S35, the machine learning model 24 may be trained based on errors of the second output OUT2. The errors of the second output OUT2 may correspond to the differences between expected values (or measured values) of the second output OUT2 and values of the second output OUT2. The machine learning model 24 may be trained in various ways. For example, the machine learning model 24 may include an artificial neural network, and weights of the artificial neural network may be adjusted based on values back-propagated from the errors of the second output OUT2. An example of operation S35 will be described with reference to FIG. 4 below.

FIG. 4 is a flowchart of a method for a hybrid model according to an example embodiment. The flowchart of FIG. 4 is an example of operation S35 of FIG. 3. As described above with reference to FIG. 3, the machine learning model 24 may be trained based on errors of the second output OUT2 in operation S35′ of FIG. 4. As illustrated in FIG. 4, operation S35′ may include operations S35_1 and S35_2. FIG. 4 will be described below with reference to FIG. 2.

In operation S35_1, a loss function may be calculated based on the errors of the second output OUT2. The loss function may be defined to evaluate the second output OUT2 generated from the first input IN1 and the second input IN2, and may also be referred to as a cost function. The loss function may define a value that increases as the difference between the second output OUT2 and an expected value (or a measured value) increases. In embodiments, a value of the loss function may increase as the errors of the second output OUT2 increase. Thereafter, in operation S35_2, the machine learning model 24 may be trained to reduce a result value of the loss function.

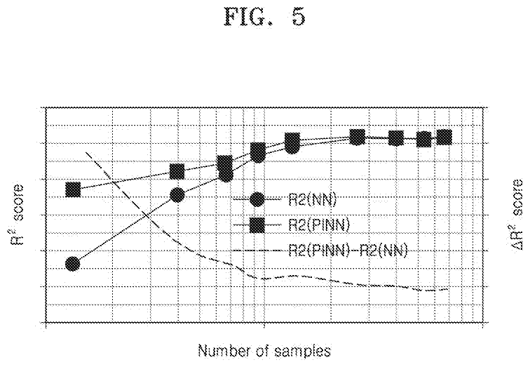

FIG. 5 is a graph showing a performance of a hybrid model according to an example embodiment. The graph of FIG. 5 shows the performance of a single machine learning model indicated by “R2(NN)” and the performance of the hybrid model 20 of FIG. 2 indicated by “R2(PINN)” according to the number of samples, and shows a deviation between the performance of the learning model and the performance of the hybrid model 20 as indicated by a dashed line. The horizontal axis of the graph of FIG. 5 represents the number of samples, and the vertical axis thereof represents an R² (R-squared) score indicating the performance of a model. FIG. 5 will be described below with reference to FIG. 2.

In embodiments, the hybrid model 20 of FIG. 2 may be used to estimate characteristics of an integrated circuit fabricated by a semiconductor process. The first input IN1 and the second input IN2 may be process parameters of the semiconductor process, and the second output OUT2 may correspond to characteristics of an integrated circuit manufactured by the semiconductor process. For example, when the hybrid model 20 is used to estimate a variation ΔVt of a threshold voltage of a transistor included in an integrated circuit, the rule-based model 22 may include a rule defined by Equation 1 below.

$$Δ V t = f ( M G B , {N}_{fin} , … ) = α \cdot {( \frac{1}{M G B} )}^{{c}_{1}} \cdot {( \frac{1}{{N}_{f i n}} )}^{{c}_{2}} \qquad [ Equation 1 ]$$

In Equation 1, a metal gate boundary (MGB) represents a distance of a gate from a boundary and N_{fin} represents the number of fins included in a FinFET. The first input IN1 may include MGB, N_{fin}, and the like of Equation 1. The rule-based model 22 may generate as the first output OUT1 the variation ΔVt of the threshold voltage corresponding to the first input IN1, based on Equation 1. The machine learning model 24 may receive not only the first input IN1 but also the first output OUT1, i.e., the variation ΔVt of the threshold voltage, and generate a finally estimated variation ΔVt of the threshold voltage as the second output OUT2.

Referring to FIG. 5, the performance of the hybrid model 20 may be better than the performance of the single machine learning model. A degree of reduction of the performance of the hybrid model 20 may be small even when the number of samples decreases, whereas the performance of the single machine learning model may rapidly decrease when the number of samples decreases. Accordingly, the deviation between the performance of the hybrid model 20 and the performance of the single machine learning model may not be relatively large when the number of samples is large but may increase as the number of samples decreases. Therefore, the performance of the hybrid model 20 may be good even when the amount of sample data is small.

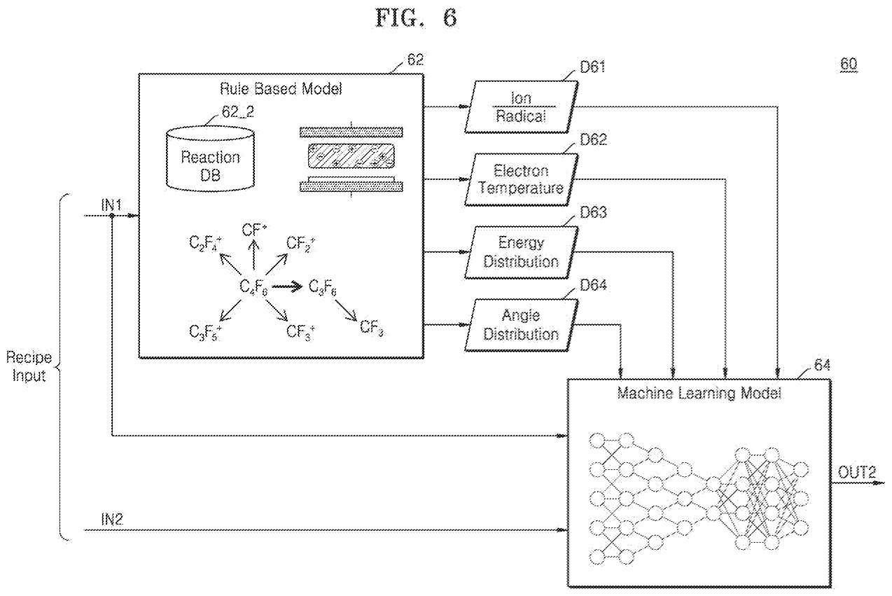

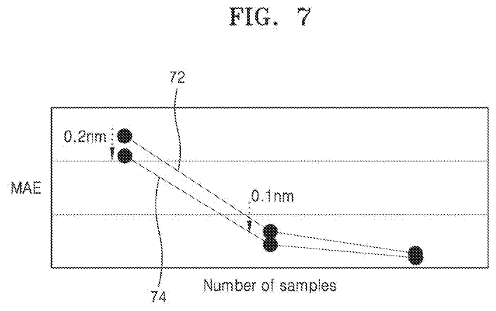

FIG. 6 is a block diagram of an example of a hybrid model 60 according to an example embodiment. FIG. 7 is a graph showing a performance of the hybrid model 60 of FIG. 6, according to an example embodiment. The block diagram of FIG. 6 shows the hybrid model 60 that is an example of the hybrid model 20 of FIG. 2 and is modeled on a plasma process included in a semiconductor process. The graph of FIG. 7 shows the performance of a single machine learning model indicated by a curve 72 and the performance of the hybrid model 60 of FIG. 6 indicated by a curve 74 according to the number of samples.

Referring to FIG. 6, the hybrid model 60 may include a rule-based model 62 and a machine learning model 64, receive a first input IN1 and a second input IN2, and generate a second output OUT2, similar to the hybrid model 20 of FIG. 2. The first input IN1 and the second input IN2 may be process parameters for setting the plasma process, and may be collectively referred to as a recipe input (or process recipe). For example, the first input IN1 and the second input IN2 may include process parameters such as temperature, a gas flow rate, and a bolt tightening degree. The second output OUT2 may include values representing a profile of a pattern formed by the plasma process and/or a degree of opening of the pattern.

The rule-based model 62 may include rules that define at least part of the plasma process. For example, as illustrated in FIG. 6, the rule-based model 62 may include a reaction database 62_2 including data collected by repeatedly performing the plasma process. The rule-based model 62 may further include formulas and/or conditions that define physical phenomena occurring in the plasma process. The rule-based model 62 may generate, as a first output OUT1, an ion/radical ratio D61, an electron temperature D62, an energy distribution D63, and am angular distribution D64 from the first input IN1, based on the rules, and provide them to the machine learning model 64.

The machine learning model 64 may receive the first input IN1 and the second input IN2, and receive, as the first output OUT1, the ion/radical ratio D61, the electron temperature D62, the energy distribution D63, and the angular distribution D64 from the rule-based model 62. The machine learning model 64 may generate the second output OUT2 from the first input IN1, the second input IN2, and the first output OUT1. The second output OUT2 may include values for accurately estimating a profile of a pattern formed by the plasma process and/or a degree of opening of the pattern.

The horizontal axis of the graph of FIG. 7 represents the number of samples, and the vertical axis thereof represents a mean absolute error (MAE). Both a single machine learning model and the hybrid model 60 may provide an MAE that decreases as the number of samples increases. However, the hybrid model 60 may provide an overall lower MAE than the single machine learning model, and furthermore, a deviation between the performance of the hybrid model 60 and the performance of the single machine learning model may increase as the number of samples decreases. Accordingly, the hybrid model 60 may be more advantageously used as the amount of sample data is insufficient.

FIG. 8 is a flowchart of a method for a hybrid model according to an example embodiment. The flowchart of FIG. 8 is a method for the hybrid model 20 of FIG. 2, in which the machine learning model 24 is trained and the rules included in the rule-based model 22 are modified. As illustrated in FIG. 8, the method for the hybrid model 20 may include a plurality of operations S81 to S86. A description of a part of FIG. 8 that is the same as that of FIG. 3 will be omitted here, and FIG. 8 will be described below with reference to FIG. 2.

Referring to FIG. 8, a first input IN1 may be provided to the rule-based model 22 in operation S81, and a first output OUT1 may be obtained from the rule-based model 22 in operation S82. Next, the first input IN1, a second input IN2, and the first output OUT1 may be provided to the machine learning model 24 in operation S83, and a second output OUT2 may be obtained from the machine learning model 24 in operation S84. In operation S85, the machine learning model 24 may be trained based on errors of the second output OUT2.

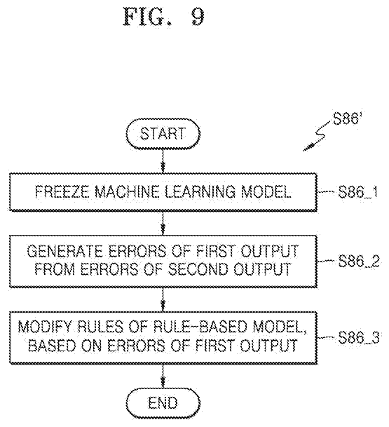

In operation S86, rules of the rule-based model 22 may be modified based on the errors of the second output OUT2. For example, the rule-based model 22 may include a plurality of parameters used to generate the first output OUT1 from the first input IN1, and any one or any combination of the plurality of parameters may be modified based on the errors of the second output OUT2. Accordingly, the machine learning model 24 may be trained in operation S85 and the rules of the rule-based model 22 may be modified in operation S86, thereby increasing the accuracy of the hybrid model 20. An example of operation S86 will be described with reference to FIG. 9 below.

In embodiments, the machine learning model 24 may be trained based on a degree to which the rules included in the rule-based model 22 are modified. The rules included in the rule-based model 22 may be defined based on physical phenomena, and thus, the machine learning model 24 may be trained such that fewer modifications are made to the rules included in the rule-based model 22. For example, operation S85 of FIG. 8 may include operations S35_1 and S35_2 of FIG. 4, and the loss function used in operation S85 may increase as a degree to which the plurality of parameters included in the rule-based model 22 are changed increases. For example, when the rule-based model 22 includes N parameters (here, N is an integer greater than 0), a loss function L(0) may be defined by Equation 2 below.

$$L ( θ ) = {L}_{n e w} ( θ ) + \frac{λ}{2} {\sum }_{1 \leq n \leq N} {{F}_{n} ( {θ}_{n} - {θ}_{n}^{*} )}^{2} \qquad [ Equation 2 ]$$

L_{new}(θ), which is the first term of Equation 2, may correspond to the errors of the second output values OUT2 or values derived from the errors. In the second term of Equation 2, λ may be a constant determined according to the weights of training both the machine learning model 24 and the rule-based model 22 for regularization thereof, θₙ may represent an n^{th} parameter included in the rule-based model 22 before the rule-based model is adjusted, θₙ* may represent an n^{th} parameter after the rule-based model is adjusted, and Fₙ may be a constant determined according to the importance of the n^{th} parameter. As errors between the plurality of parameters included in the rule-based model 22 and the adjusted plurality of parameters increase, the second term of Equation 2 may increase and thus a value of the loss function L(θ) may also increase. As described above with reference to FIG. 4, the machine learning model 24 may be trained to reduce a value of the loss function L(θ), and thus may be trained such that fewer modifications are made to the rules included in the rule-based model 22.

FIG. 9 is a flowchart of a method for a hybrid model according to an example embodiment. The flowchart of FIG. 4 is an example of operation S86 of FIG. 8. As described above with reference to FIG. 8, in operation S86′ of FIG. 9, the rules of the rule-based model 22 may be modified based on the errors of the second output OUT2. As illustrated in FIG. 9, operation S86′ may include a plurality of operations S86_1 to S86_3. FIG. 9 will be described below with reference to FIGS. 2 and 8.

In operation S86_1, the machine learning model 24 may be frozen. For example, values of internal parameters of the machine learning model 24 may be changed in a process of training the machine learning model 24 in operation S85 of FIG. 8. Moreover, to analyze an effect of the rule-based model 22 on the second output OUT2, the machine learning model 24 may be frozen and thus the values of the internal parameters of the machine learning model 24 may be prevented from being changed.

In operation S86_2, errors of the first output OUT1 may be generated from errors of the second output OUT2. For example, the errors of the first output OUT1 due to the errors of the second output OUT2 may be generated from the machine learning model 24 frozen in operation S86_1 while the first input IN1 and the second input IN2 are given. In some embodiments, when the machine learning model 24 includes an artificial neural network, the errors of the first output OUT1 may be calculated from the errors of the second output OUT2 while weights included in the artificial neural network are fixed.

In operation S86_3, the rules of the rule-based model 22 may be modified based on the errors of the first output OUT1. For example, any one or any combination of the plurality of parameters included in the rule-based model 22 may be adjusted, based on the given first input IN1 and the errors of the first output OUT1. Accordingly, the rule-based model 22 may include rules modified according to the adjusted parameters.

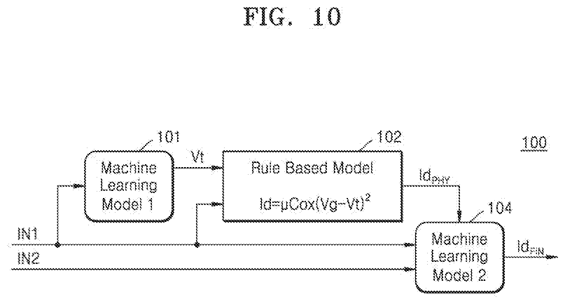

FIG. 10 is a block diagram of an example of a hybrid model 100 according to an example embodiment. The block diagram of FIG. 10 shows the hybrid model 100, which is an example of the hybrid model 20 of FIG. 2, for estimating drain current Id of a transistor included in an integrated circuit manufactured by a semiconductor process. As illustrated in FIG. 10, the hybrid model 100 may include a first machine learning model 101, a rule-based model 102, and a second machine learning model 104. In the hybrid model 100 of FIG. 10, rules included in the rule-based model 102 may be modified as described above with reference to FIG. 8.

The first machine learning model 101 may receive a first input IN1 as process parameters and may output a threshold voltage Vt of the transistor from the first input IN1. In some embodiments, unlike that illustrated in FIG. 10, the hybrid model 100 may include a rule-based model for generating the threshold voltage Vt from the first input IN1 instead of the first machine learning model 101.

The rule-based model 102 may receive the first input IN1, receive the threshold voltage Vt from the first machine learning model 101, and output drain current Id_{PHY} physically estimated from the first input IN1 and the threshold voltage Vt. As illustrated in FIG. 10, the rule-based model 102 may include a rule defined by Equation 3 below.

Id=μCox(Vg−Vt)² [Equation 3]

In Equation 3, μ, may represent the mobility of electrons (or holes), Cox may represent a gate capacitance per unit area, and Vg may represent a gate voltage.

The second machine learning model 104 may receive the first input IN1, the second input IN2, and the physically estimated drain current Id_{PHY}, and output drain current Id_{FIN} finally estimated from the first input IN1, the second input IN2, and the estimated drain current Id_{PHY}.

In some embodiments, the rules included in the rule-based model 102 may be modified, as well as the first machine learning model 101 and the second machine learning model 104. For example, in the rule defined by Equation 3, μ, representing electron mobility may be modified (or corrected) based on Equation 4 below.

μ=g(μₘᵢₙ,μₘₐₓ) [Equation 4]

In Equation 4, μₘᵢₙ may represent a minimum value of the electron mobility μ determined by errors of the physically estimated drain current Id_{PHY}, and μₘₐₓ may represent a maximum value of the electron mobility μ determined by the errors of the physically estimated drain current Id_{PHY}. The electron mobility μ may be defined by a function g of the minimum value μₘᵢₙ and the maximum value μₘₐₓ, and the rule defined by Equation 3 may be modified according thereto. According to an experiment, with respect to about 100 samples, the performance of the hybrid model 100 may be three times or more better than that of a single machine learning model.

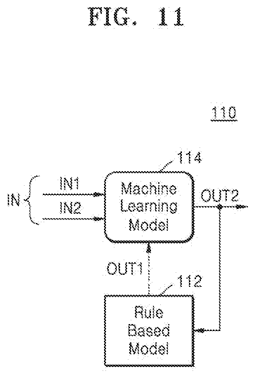

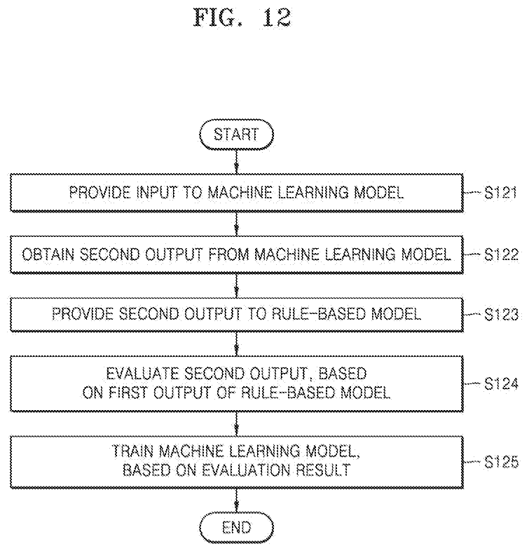

FIG. 11 is a block diagram of an example of a hybrid model 110 according to an example embodiment. FIG. 12 is a flowchart of a method for the hybrid model 110 of FIG. 11, according to an example embodiment. As illustrated in FIG. 11, the hybrid model 110 may include a rule-based model 112 and a machine learning model 114, and may receive a first input IN1 and a second input IN2 and generate a second output OUT2 as the output OUT of FIG. 1 as described above with reference to FIG. 1. The first input IN1 and the second input IN2 may be collectively referred to as an input IN. As illustrated in FIG. 12, a method for the hybrid model 110 may include a plurality of operations S121 to S125.

Referring to FIG. 11, the hybrid model 110 of FIG. 11 may include the machine learning model 114 that receives the first input IN1 and the second input IN2, and the rule-based model 112 that receives the second output OUT2 generated by the machine learning model 114. Unlike the hybrid model 20 of FIG. 2 in which the first output OUT1 of the rule-based model 22 is provided to the machine learning model 24, the rule-based model 112 of FIG. 11 may generate the first output OUT1 from the second output OUT2 of the machine learning model 114, based on at least one rule. The first output OUT1 may be fed back as a result of evaluating the second output OUT2 to the machine learning model 114 as indicated by the dashed line in FIG. 11.

Referring to FIG. 12, an input IN may be provided to the machine learning model 114 in operation S121, and a second output OUT2 may be obtained from the machine learning model 114 in operation S122. The input IN may include a first input IN1 and a second input IN2, and the machine learning model 114 may generate a second output OUT2 from the first input IN1 and the second input IN2.

In operation S123, the second output OUT2 may be provided to the rule-based model 112. In operation S124, the second output OUT2 may be evaluated based on the first output OUT1 of the rule-based model 112. In some embodiments, the rule-based model 112 may include a rule defining an allowable range of the second output OUT2, and the second output OUT2 may be evaluated better (a score of evaluating the second output OUT2 may be increased) as it approaches the allowable range. In embodiments, the rule-based model 112 may include as a rule a formula defined by the second output OUT2, and the second output OUT2 may be evaluated better (the score of evaluating the second output OUT2 may be increased) as it approximates the formula. In embodiments, the first output OUT1 may have a value that increases or decreases as the result of evaluating the second output OUT2 is better or increases.

In operation S125, the machine learning model 114 may be trained based on the evaluation result. In some embodiments, operation S125 may include operations S35_1 and S35_2 of FIG. 4, and a value of a loss function used in operation 51125 may decrease as the result or a score of evaluating the second output OUT2 is better or increases. Accordingly, the machine learning model 114 may be trained based on the rule included in the rule-based model 112.

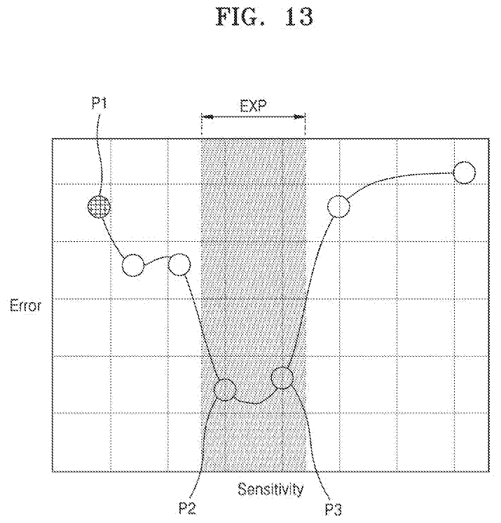

FIG. 13 is a graph showing a performance of a hybrid model according to an example embodiment. The graph of FIG. 13 shows the amount of change of a dimension of a pattern formed in an integrated circuit according to a flow rate of a gas. The horizontal axis of the graph of FIG. 13 represents sensitivity representing a change of dimension with respect to a unit flow rate, and the vertical axis thereof represents an error between a change of dimension measured actually and a change of dimension estimated using a model. FIG. 13 will be described below with reference to FIG. 11.

Based on a large number of experiments, a rule that a change of dimension with respect to a flow rate of a gas, i.e., sensitivity, is within a range EXP may be predefined, and the rule-based model 112 may include the predefined rule. When a single machine learning model is used, sensitivity beyond the range EXP may be estimated as indicated by “P1” in FIG. 13, and the estimated sensitivity may have a high error. Moreover, the machine learning model 114 may be trained by the rule-based model 112 such that the second output OUT2 is close to the range EXP, and thus, sensitivities within the range EXP may be estimated as indicated by “P2” and “P3” of FIG. 13 and the estimated sensitivities may have a low error.

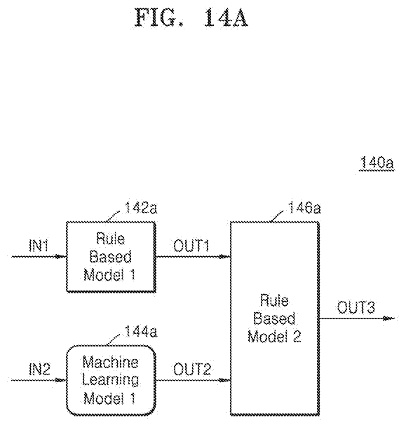

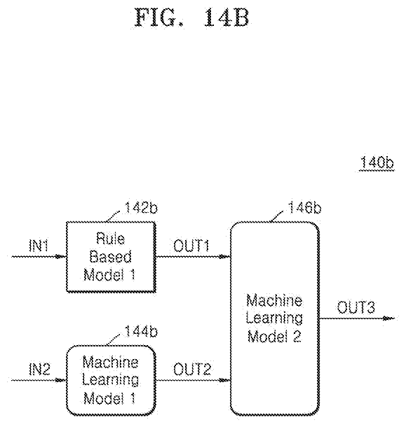

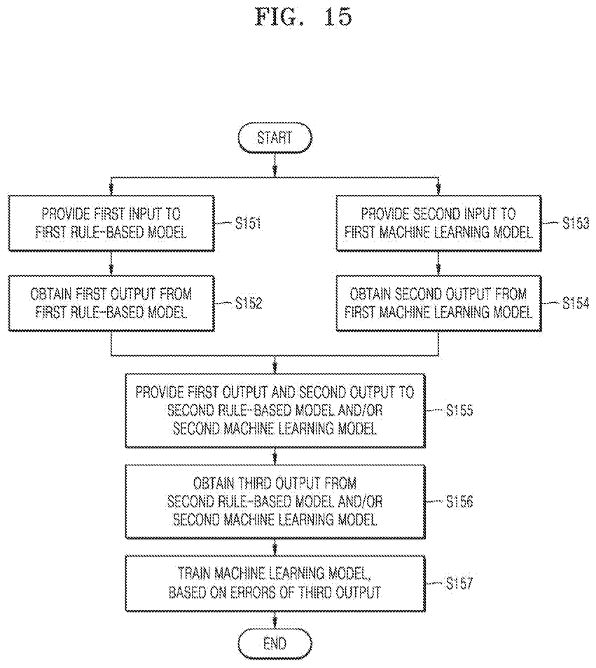

FIGS. 14A and 14B are block diagrams of examples of hybrid models 140a and 140b according to embodiments. FIG. 15 is a flowchart of a method for the hybrid models 140a and 140b of FIGS. 14A and 14B, according to embodiments. The hybrid models 140a and 140b of FIGS. 14A and 14B may generate a third output OUT3 as the output OUT of FIG. 1. A description of a part of FIG. 15 that is the same as those of FIGS. 3 and 8 will be omitted here.

Referring to FIG. 14A, the hybrid model 140a may include a first rule-based model 142a, a first machine learning model 144a, and a second rule-based model 146a. Similarly, referring to FIG. 14B, the hybrid model 140b may include a first rule-based model 142b, a first machine learning model 144b, and a second machine learning model 146b. Thus, the first rule-based models 142a and 142b of the hybrid models 140a and 140b may process an input in parallel with the first machine learning models 144a and 144b. In some embodiments, a hybrid model may include both a second rule-based model and a second machine learning model which receive a first output OUT1 and a second output OUT2 generated by the first rule-based models 142a and 142b and the first machine learning models 144a and 144b.

Referring to FIG. 15, the method for the hybrid models 140a and 140b may include a plurality of operations S151 to S157. As illustrated in FIG. 15, operations S151 and S152 may be performed in parallel with operations S153 and S154. FIG. 15 will be described below mainly with reference to FIG. 14A.

A first input IN1 may be provided to the first rule-based model 142a in operation S151, and a first output OUT1 may be obtained from the first rule-based model 142a in operation S152. A second input IN2 may be provided to the first machine learning model 144a in operation S153, and a second output OUT2 may be obtained from the first machine learning model 144a in operation S154.

The first output OUT1 and the second output OUT2 may be provided to the second rule-based model 146a and/or the second machine learning model 146b in operation S155. A third output OUT3 may be obtained from the second rule-based model 146a and/or the second machine learning model 146b in operation S156. Next, the first machine learning model 144a may be trained based on errors of the third output OUT3 in operation S157. In some embodiments, in the hybrid model 140b of FIG. 14B that includes the second machine learning model 146b, the second machine learning model 146b may be trained based on the errors of the third output OUT3.

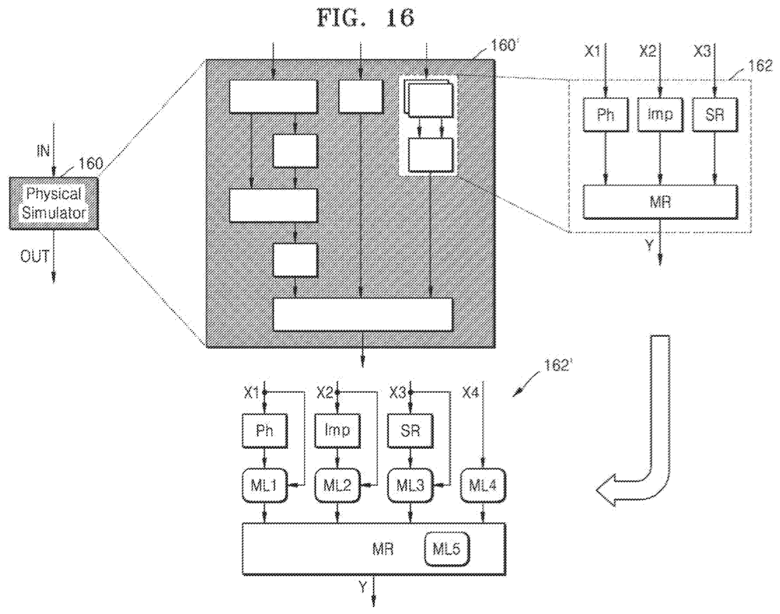

FIG. 16 is a block diagram of a physical simulator 160 including a hybrid model 162′ according to an example embodiment. In some embodiments, the hybrid model 162′ may be included in the physical simulator 160 that generates an output OUT by simulating an input IN and may improve the accuracy and efficiency of the physical simulator 160. For example, as illustrated in FIG. 16, a physical simulator 160′ may include a plurality of rule-based models that hierarchically exchange inputs and outputs, i.e., a plurality of physical models, and a part 162 of the physical simulator 160′ may be replaced with the hybrid model 162′. The hybrid model 162′ of FIG. 16 may have a structure including the examples of FIGS. 2, 14A, and 14B.

Referring to FIG. 16, the part 162 of the physical simulator 160′ may include physical models Ph, Imp, SR, and MR, and generate an output Y representing the mobility of electrons (or holes) from inputs X1, X2, and X3. The physical model Ph may receive, as the input X1, temperature, a dimension of a channel through which electrons move, etc. and generate photon mobility μₚₕ from the input X1. The photon mobility μₚₕ may indicate a level at which a crystal lattice oscillates in a channel through which electrons move. The physical model Imp may receive as the input X2 a doping concentration, a dimension of a channel, etc., and generate mobility μᵢₘₚ due to impurities from the input X2. The physical model SR may receive as the input X3 an etching parameter, a dimension of a channel, etc., and generate mobility μ_{SR} according to surface roughness from the input X3. The physical model MR may generate an output Y representing electron mobility from the phonon mobility poi, the mobility μᵢₘₚ due to impurities and the mobility μ_{SR} according to surface roughness, based on Matthiessen's rule. For example, the electron mobility μ may be calculated by Equation 5 below, and the physical model MR may include a rule defined by Equation 5 below.

$$\frac{1}{μ} = \frac{1}{{μ}_{p h}} + \frac{1}{{μ}_{imp}} + \frac{1}{{μ}_{S R}} \qquad [ Equation 5 ]$$

The hybrid model 162′ may include first to fourth machine learning models ML1 to ML4, as well as the physical models Ph, Imp and SR, and the physical model MR and the fifth machine learning model ML5 may be integrated together. For example, similar to the machine learning model 24 of FIG. 2, the first machine learning model ML1 may receive the input X1 together with the physical model Ph and receive photon mobility physically estimated from the physical model Ph. The second machine learning model ML2 may receive the input X2 together with the physical model Imp and receive mobility due to impurities physically estimated from the physical model Imp. Similarly, the third machine learning model ML3 may receive the input X3 together with the physical model SR, and receive mobility due to surface roughness, which is physically estimated from the physical model SR. In embodiments, the physical model Ph and the physical model Imp may include fixed parameters, i.e., parameters that are constants, whereas the physical model SR may include adjustable parameters and any one or any combination of the parameters of the physical model SR may be adjusted (or modified) as described above with reference to FIG. 8 or the like.

The fourth machine learning model ML4 may receive the additional input X4 and provide an output to the fifth machine learning model ML5 and the physical model MR, which are integrated together. The fifth machine learning model ML5 may be integrated with the physical model MR. For example, the physical model MR and the fifth machine learning model ML5 may process outputs of the first to fourth machine learning models ML1 to ML4 in parallel as illustrated in FIGS. 14A and 14B.

FIG. 17 is a block diagram of a computing system 170 including a memory storing a program according to an example embodiment. At least some of operations included in a method for a hybrid model may be performed in the computing system 170. In some embodiments, the computing system 170 may be referred to as a system for a hybrid model.

The computing system 170 may be a stationary computing system, such as a desktop computer, a workstation, or a server, or a mobile computing system such as a laptop computer. As illustrated in FIG. 17, the computing system 170 may include a processor 171, input/output (I/O) devices 172, a network interface 173, random access memory (RAM) 174, read-only memory (ROM) 175, and a storage device 176. The processor 171, the I/O devices 172, the network interface 173, the RAM 174, the ROM 175, and the storage device 176 may be connected to a bus 177 and communicate with each other via the bus 177.

The processor 171 may be referred to as a processing unit, for example, a micro-processor, an application processor (AP), a digital signal processor (DSP), or a graphics processing unit (GPU), and include at least one core capable of executing an instruction set (e.g., IA-32 (Intel Architecture-32), 64-bit extensions IA-32, x86-64, PowerPC, Sparc, MIPS, or ARM, IA-64). For example, the processor 171 may access memory, i.e., the RAM 174 or the ROM 175, via the bus 177, and execute instructions stored in the RAM 174 or the ROM 175.

The RAM 174 may store a program 174_1 for performing a method for a hybrid model or at least a part thereof, and the program 174_1 may cause the processor 171 to perform at least some of operations included in the method for the hybrid model. That is, the program 174_1 may include a plurality of instructions executable by the processor 171, and the plurality of instructions in the program 174_1 may cause the processor 171 to perform at least some of the operations included in the method described above.

The storage device 176 may retain data stored therein even when power supplied to the computing system 170 is cut off. Examples of the storage device 176 may include a non-volatile memory device or a storage medium such as a magnetic tape, an optical disk, or a magnetic disk. The storage device 176 may be detachable from the computing system 170. The storage device 176 may store the program 174_1 according to embodiments. The program 174_1 or at least a part thereof may be loaded from the storage device 176 to the RAM 174 before the program 174_1 is executed by the processor 171. Alternatively, the storage device 176 may store a file written in a programming language, and the program 174_1 generated by a compiler or the like from the file or at least a part thereof may be loaded to the RAM 174. As illustrated in FIG. 17, the storage device 176 may store a database 176_1, and the database 176_1 may include information, e.g., sample data, which is used to perform the method for a hybrid model.

The storage device 176 may store data to be processed or data processed by the processor 171. That is, the processor 171 may generate data by processing data stored in the storage device 176 according to the program 174_1, and store the generated data in the storage device 176.

The I/O devices 172 may include an input device, such as a keyboard or a pointing device, and an output device such as a display device or a printer. For example, a user may trigger execution of the program 174_1, input training data, or check result data by the processor 171 through the I/O devices 172.

The network interface 173 may provide access to a network outside the computing system 170. For example, the network may include a large number of computing systems and communication links, and the communication links may include wired links, optical links, wireless links, or any other form of links.

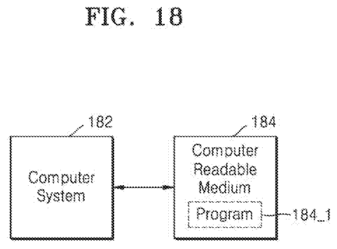

FIG. 18 is a block diagram of a computer system 182 accessing a storage medium storing a program according to an example embodiment. At least some of operations included in a method for a hybrid model may be performed by the computer system 182. The computer system 182 may access a computer-readable medium 184 and execute a program 184_1 stored in the computer-readable medium 184. In some embodiments, the computer system 182 and the computer-readable medium 184 may be collectively referred to as a system for a hybrid model.

The computer system 182 may include at least one computer subsystem, and the program 184_1 may include at least one component executed by at least one computer subsystem. For example, the at least one component may include a rule-based model and a machine learning model as described above with reference to the drawings, and include a model trainer that trains a machine learning model or modifies rules included in a rule-based model. The computer-readable medium 184 may include a non-volatile memory device, similar to the storage device 176 of FIG. 17, and may include a storage medium such as a magnetic tape, an optical disk, or a magnetic disk. The computer-readable medium 184 may be detachable from the computer system 182.

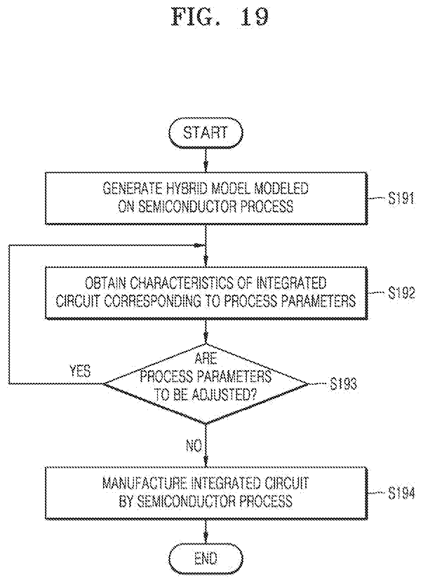

FIG. 19 is a flowchart of a method for a hybrid model according to an example embodiment. The flowchart of FIG. 19 shows a method of manufacturing an integrated circuit by using a hybrid model. As illustrated in FIG. 19, the method for a hybrid model may include a plurality of operations S191 to S194.

In operation S191, a hybrid model modeled on a semiconductor process may be generated. For example, the hybrid model may be generated by modeling any one or any combination of a plurality of processes included in the semiconductor process. As described above with reference to the drawings, the hybrid model may include at least one rule-based model (or physical model) and at least one machine learning model, and may be generated to output characteristics of an integrated circuit by receiving process parameters.

In operation S192, characteristics of an integrated circuit corresponding to process parameters may be obtained. For example, the characteristics of the integrated circuit, e.g., electron mobility and a dimension and profile of a pattern, may be obtained by providing the process parameters to the hybrid model generated in operation S191. As described above with reference to the drawings, the obtained characteristics of the integrated circuit may have high accuracy regardless of a small amount of sample data provided to the hybrid model.

In operation S193, whether the process parameters are to be adjusted may be determined. For example, it may be determined whether the characteristics of the integrated circuit obtained in operation S192 satisfy requirements. When the characteristics of the integrated circuit do not satisfy the requirements, the process parameters may be adjusted and operation S192 may be performed again. Alternatively, when the characteristics of the integrated circuit satisfy the requirements, operation S194 may be subsequently performed.

In operation S194, an integrated circuit may be manufactured by a semiconductor process. For example, an integrated circuit may be manufactured by a semiconductor process to which the process parameters finally adjusted in operation S193 are applied. The semiconductor process may include a front-end-of-line (FEOL) process and a back-end-of-line (BEOL) process in which masks fabricated based on an integrated circuit are used. For example, the FEOL process may include planarizing and cleaning a wafer, forming trenches, forming wells, forming gate lines, forming a source and a drain, and the like. The BEOL process may include silicidating gate, source and drain regions, adding a dielectric, performing planarization, forming holes, adding a metal layer, forming vias, forming a passivation layer, and the like. The integrated circuit manufactured in operation S194 may have characteristics that match the characteristics, which are obtained in operation S192, with high accuracy due to high accuracy of the hybrid model. Accordingly, a time and costs for manufacturing an integrated circuit with desirable characteristics may be reduced, and an integrated circuit with better characteristics may be manufactured.

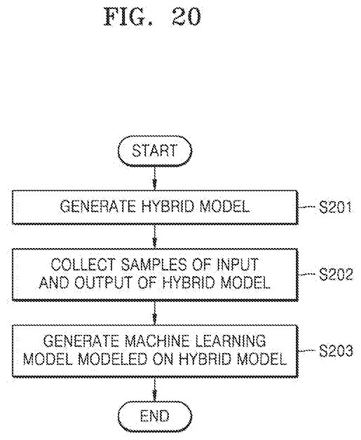

FIG. 20 is a flowchart of a method for a hybrid model according to an example embodiment. The flowchart of FIG. 20 shows a method of modeling a hybrid model. As illustrated in FIG. 20, the method for a hybrid model may include a plurality of operations S201 to S203.

In operation S201, a hybrid model may be generated. For example, as described above with reference to the drawings, a hybrid model that includes a rule-based model and a machine learning model may be generated. The hybrid model may provide high efficiency and accuracy. Next, in operation S202, samples of an input and an output of the hybrid model may be collected. For example, samples of an input may be provided to the hybrid model, and samples of an output corresponding to the samples of the input may be obtained from the hybrid model.

In operation S203, a machine learning model modeled on the hybrid model may be generated. In some embodiments, a machine learning model (e.g., an artificial neural network) may be generated by modeling the hybrid model to reduce computing resources to be consumed in implementing a hybrid model including a rule-based model and a machine learning-based model. To this end, the machine learning model modeled on the hybrid model may be trained with the samples of the input and the output collected in operation S202. The trained machine learning model may provide relatively low accuracy when compared to the hybrid model but be implemented with reduced computing resources.

As is traditional in the field of the technical concepts, the embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the technical concepts. Further, the blocks, units and/or modules of the embodiments may be physically combined into more complex blocks, units and/or modules without departing from the scope of the technical concepts.

While example embodiments been shown and described, it will be understood that various changes in form and details may be made therein without departing from the spirit and scope of the following claims.

1. A method for a hybrid model that comprises a machine learning model and a rule-based model, the method comprising:
obtaining a first output from the rule-based model by providing a first input to the rule-based model;
obtaining a second output from the machine learning model by providing the first input, a second input, and the obtained first output to the machine learning model; and
training the machine learning model, based on errors of the obtained second output.

2. The method of claim 1, wherein the first input is required for the rule-based model, and
the second input affects the second output and is not required for the rule-based model.

3. The method of claim 1, wherein the rule-based model comprises a plurality of parameters used to obtain the first output from the first input, and
each of the plurality of parameters is a constant.

4. The method of claim 1, wherein the rule-based model comprises a plurality of parameters used to obtain the first output from the first input, and
the method further comprises adjusting the plurality of parameters, based on the errors of the obtained second output.

5. The method of claim 4, wherein the training of the machine learning model comprises:
obtaining a value of a loss function, based on the errors of the obtained second output; and
training the machine learning model to reduce the value of the obtained loss function, and
wherein the value of the obtained loss function increases as errors between the plurality of parameters and the adjusted plurality of parameters increase.

6. The method of claim 4, wherein the adjusting of the plurality of parameters comprises:
freezing the machine learning model;
obtaining errors of the obtained first output from the errors of the obtained second output, while the machine learning model is frozen; and
modifying the plurality of parameters, based on the obtained errors of the first output.

7. The method of claim 1, further comprising:
collecting samples of the first input, the second input, and the obtained second output, using the hybrid model; and
obtaining a machine learning model that is modeled on the hybrid model, based on the collected samples of the first input, the second input, and the obtained second output.

8. The method of claim 1, wherein the rule-based model comprises at least one of a physical simulator, an emulator that is modeled on the physical simulator, an analytical rule, a heuristic rule, or an empirical rule.

9. The method of claim 1, wherein the machine learning model comprises an artificial neural network, and
the training of the machine learning model comprises adjusting weights of the artificial neural network, based on values that are backpropagated from the errors of the obtained second output.

10. The method of claim 1, wherein each of the first input and the second input comprises process parameters of a semiconductor process for manufacturing an integrated circuit, and
the second output corresponds to characteristics of the integrated circuit.

11. The method of claim 10, further comprising manufacturing the integrated circuit, based on the process parameters.

12. A method for a hybrid model that comprises a machine learning model and a rule-based model, the method comprising:
obtaining an output from the machine learning model by providing an input to the machine learning model;
evaluating the obtained output by providing the obtained output to the rule-based model; and
training the machine learning model, based on a result of the obtained output being evaluated.

13. The method of claim 12, wherein the training of the machine learning model comprises:
obtaining a value of a loss function, based on errors of the obtained output; and
training the machine learning model to reduce the value of the obtained loss function, and
the value of the obtained loss function decreases as a score of the obtained output being evaluated increases.

14. The method of claim 12, wherein the rule-based model comprises a rule having an allowable range of the output, and
a score of the obtained output being evaluated increases as the obtained output approaches the allowable range.

15. The method of claim 12, wherein the rule-based model comprises a formula corresponding to the output, and
a score of the obtained output being evaluated increases as the obtained output approaches the formula.

16. The method of claim 12, further comprising:
collecting samples of the input and the obtained output, using the hybrid model; and
obtaining a machine learning model that is modeled on the hybrid model, based on the collected samples of the input and the obtained output.

17-20. (canceled)

21. A method for a hybrid model that comprises a plurality of machine learning models and a plurality of rule-based models, the method comprising:
obtaining a first output from a first rule-based model by providing a first input to the first rule-based model;
obtaining a second output from a first machine learning model by providing a second input to the first machine learning model;
obtaining a third output by providing the obtained first output and the obtained second output to a second rule-based model or a second machine learning model; and
training the first machine learning model, based on errors of the obtained third output.

22. The method of claim 21, wherein the first input is for the first rule-based model, and
the second input affects the third output but is not for the first rule-based model.

23. The method of claim 21, wherein the first rule-based model comprises a plurality of parameters to be used to obtain the first output from the first input, and
the method further comprises adjusting the plurality of parameters, based on the errors of the obtained third output.

24. The method of claim 23, wherein the training of the first machine learning model comprises:
obtaining a value of a loss function, based on the errors of the obtained third output; and
training the first machine learning model to reduce the value of the obtained loss function, and
the value of the obtained loss function increases as errors between the plurality of parameters and the adjusted plurality of parameters increase.

25-28. (canceled)
